(19) United States
(12) Patent Application Publication
(10) Pub. No.: US 2005/0084611 A1
(43) Pub. Date: Apr. 21, 2005

(54) Structures and method for producing thereof

(75) Inventors: Kikuo Okuyama, Higashihiroshima-shi (JP); Hiroyuki Hirai, Minami-ashigara-shi (JP)

Correspondence Address: BURNS DOANE SWECKER & MATHIS L L P, POST OFFICE BOX 1404, ALEXANDRIA, VA, 22313-1404, US

(73) Assignee: FUJI PHOTO FILM CO., LTD.

(21) Appl. No.: 10/958,293

(22) Filed: Oct. 6, 2004

Related U.S. Application Data
(62) Division of application No. 10/315,127, filed on Dec. 10, 2002, now abandoned.

(30) Foreign Application Priority Data
Dec. 11, 2001 (JP) 376853/2001

(51) Int. Cl. C23C 16/00

(52) U.S. Cl. 427/248.1; 427/250; 427/372.2

(57) ABSTRACT

A novel method for producing a structure having cavities is disclosed. The method comprises a first step of coating a colloidal dispersion liquid on a substrate and then drying to thereby form a layer of colloidal beads on said substrate; a second step of forming a film comprising a metal and/or metal compound on surfaces of said colloidal beads placed on said substrate; and a third step of removing said colloidal beads thereby to form cavities in place of said colloidal beads.

### TECHNICAL FIELD

The present invention relates to a method for producing a structure having fine cavities, a method for producing a structure having fine particles, and the novel structures which can be produced-by the methods.

### RELATED ART

Structures having fine pores are used in a wide variety of fields including optics, chemistry, semiconductor manufacturing and separation/purification technology. Various applications have been proposed. For example, there is an application of pores of the structure, being added functionality, to a reaction site; an application the porous material being added functionality to a structured material having independent fine functional structures organized therein; and an application of the porous material to a template for manufacturing nano-structured materials such as nano-bead and photonic crystal. It can thus be said that the porous material plays an important role in development of new materials which may be capable of improving absorption process, catalytic reaction process and so forth. These functions of the porous material are determined by the structure thereof, and more specifically by the porous region and porosity. It is thus important in the development of novel materials having the foregoing functions to provide the porous material having a pore size of the order of micrometer to nanometer which is well suited to molecular size.

Velev et al. proposed a method for synthesizing a metal material having a nano-scale regularity and a hierarchical porosity, which was obtained by regularly arranging colloidal beads and then by filling nano-particles of a metal such as gold or silver into the gap between thus arranged colloidal beads (Nature 1999, 401, p.548; Adv. Mater. 1999, 11, p.165; and Adv. Mater. 2000, 12, p.53). Another proposal relates to a method of manufacturing meso-porous material comprised of nickel, cobalt or iron in which a correspondent metal oxalate is first decomposed to produce a porous metal oxide, and the product is then reduced with hydrogen (Yan H., Adv. Mater. 1999, 11, p.1003). Yet still other reports include that describing a method for manufacturing a porous material comprised of copper, silver, platinum or gold based on electroless plating of a correspondent metal nano-particles (Jaing P., J. Am. Chem. Soc. 1999, 121, p.7957); and that describing a method for manufacturing a porous structured material based on anodizing of aluminum.

All of the foregoing manufacturing methods are, however, disadvantageous in that being time-consuming since they are based on combinations of a large number of process steps and complicated chemical reactions. Moreover, only a specific range of metal materials are available. For example, the above-described method using a metal colloid as reported by Velev et al. allows use of only such metals capable of forming colloid, and is not applicable for the case where the colloidal beads may collapse. Other methods solely rely upon liquid-phase reactions suffer from a drawback such that the obtained structured materials tend to be contaminated and to fail in obtaining desired functions. Another disadvantage resides in that interaction between fine particles under a liquid status and colloidal beads may cause non-uniform filling.

### SUMMARY OF THE INVENTION

One object of the present invention is to provide methods for readily and rapidly producing a structure having fine cavities regularly arranged, and a structure having fine particles regularly arranged in a dot pattern by adjusting setting of the conditions. Another object of the present invention is also to provide a novel structure having fine cavities regularly arranged, and a novel structure having fine particles regularly arranged in a dot pattern.

One aspect of the present invention relates to a method for producing a structure having cavities comprising:

a first step of coating a colloidal dispersion liquid on a substrate and then drying to thereby form a layer of colloidal beads on said substrate;

a second step of forming a film comprising a metal and/or metal compound on surfaces of said colloidal beads placed on said substrate; and

a third step of removing said colloidal beads thereby to form cavities in place of said colloidal beads.

As preferred embodiments, there are provided the method wherein said colloidal beads are made of an organic material; the method wherein said film in said second step is formed by depositing a metal and/or metal compound on the surface of said colloidal beads by the vapor phase process or by the liquid phase process; the method wherein said colloidal beads in said third step are removed by decomposition, vaporization and/or sublimation under heating; the method wherein said colloidal beads in said third step are removed by decomposition, vaporization and/or sublimation while being heated to a temperature lower than the fusing temperature of said film; and the method wherein said colloidal beads in said third step are removed by dissolving said colloidal beads into a solvent.

Another aspect of the present invention relates to a structure comprising a substrate and a plurality of structural units made of a metal and/or metal compound, wherein each of said structural units has a form of hollow cup with its opening toward said substrate and is organized according to a continual arrangement.

As preferred embodiments, there are provided the structure which has a characteristic equivalent to crystallinity exhibited by a correspondent bulk metal in X-ray diffractometer; and the structure which is produced by said method.

Another aspect of the present invention relates to .a method for manufacturing a structure having fine particles regularly arranged on a substrate, said method comprising:

a first step of coating a colloidal dispersion liquid on a substrate and then drying to thereby form a layer of colloidal beads on said substrate;

a second step of forming a film comprising a metal and/or metal compound on the surface of said colloidal beads placed on said substrate;

a third step of removing said colloidal beads thereby to form cavities in place of said colloidal beads; and

a fourth step of fusing and collapsing said film by heating to thereby transform into said fine particles,

wherein said fourth step is carried out simultaneously with said third step or after said third step.

As preferred embodiments, there are provided the method wherein said colloidal beads are made of an organic material; the method wherein said film in said second step is formed by depositing a metal and/or metal compound on the surfaces of said colloidal beads by the vapor phase process or the liquid phase; the method wherein said film in said second step is formed by depositing a metal and/or metal compound on the surfaces of said colloidal beads by the liquid phase process; the method wherein said colloidal beads in said third step are removed by decomposition, vaporization and/or sublimation under heating; the method wherein said colloidal beads in said third step are removed by decomposition, vaporization and/or sublimation while being heated to a temperature lower than the fusing temperature of said film; the method wherein said colloidal beads in said third step are removed by dissolving said colloidal beads into a solvent.

Another aspect of the present invention relates to a structural having fine particles regularly arranged on a substrate, which is produced by said method.

### BRIEF DESCRIPTION OF THE DRAWINGS

FIGS. 1(a) through 1(e) are conceptual schematic drawing showing one embodiment of the present invention.

FIG. 2 is a graph showing a temperature cycle during calcination in an Example.

FIGS. 3(a) through 3(d) are SEM images of samples having ameso-cups structures in the Example.

FIG. 4 is an SEM image of the individual meso-cups contained in the sample produced in the Example

FIG. 5 is an X-ray diffraction chart showing patterns for the samples having a meso-cups structure or a meso-dots structure produced in the Examples.

FIGS. 6(a) through 6(c) are SEM images of the sample having a meso-dots structure produced in the Examples.

### DETAILED DESCRIPTION OF THE INVENTION

The present invention will specifically be described with reference to preferred embodiments, while not being limited thereto.

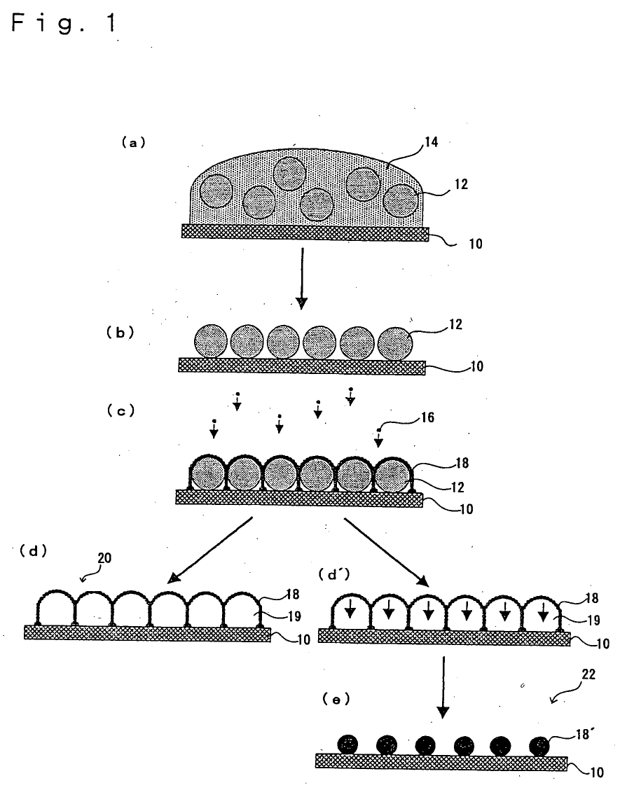

One embodiment of the present invention is shown in FIGS. 1(a) through 1(e).

First a dispersion liquid 14 of colloidal beads 12 such as those made of polystyrene latex is prepared. The colloidal dispersion liquid 14 is then coated on a substrate 10 such as silicon wafer (FIG. 1(a)). Succeeding drying of the solvent contained in the droplets of the colloidal dispersion liquid 14 allows the colloidal beads 12 to regularly organize on the substrate 10 (FIG. 1(b)). Fine particles 16 of a metal and/or metal compound are then deposited by sputtering or the like on the colloidal beads 12, where the fine particles 16 also deposit in the gap elsewhere between the adjacent particles to thereby form a film 18 typically comprised of a metal so as to cover the colloidal beads 12 (FIG. 1 (c)) The film 18 covers the colloidal beads 12 in a form of cups individually placed facedown. The colloidal beads 12 are then removed by decomposition, vaporization and/or sublimation under heating to a temperature lower than the fusing temperature of the film 18, or by dissolving them into a solvent, so as to empty the film 18 and to produce fine cavities 19 in place of the colloidal beads 12 (FIG. 1(d)). By these process steps, a structure 20 is formed on the substrate 10, where the structure 20 comprises the film 18 having cup-formed structures arranged according to a two-dimensional regularity while directing the openings thereof toward (facedown) the substrate 10. A structure of the film 18 formed on the substrate 10 can be referred to as “meso-cups”.

After the removal of the colloidal beads 12, or simultaneously with the removal of the colloidal beads 12, the film 18 is heated to a temperature not lower than the fusing temperature thereof, which allows the film 18 to fuse and collapse toward the substrate 10 (FIG. 1(d′)). Further heating allows the film 18 to transform into dot-patterned fine particles 18′, which produces a structure 22 having such fine particles 18′ arranged on the substrate 10 according to a two-dimensional dimensional regularity. A structure of the fine particles 18′ formed on the substrate 10 can be referred to as “meso-dots”.

According to the embodiment of the present invention, the structure having the meso-cups and the structure having the meso-dots can be produced within a short time. Selecting a proper size for the colloidal beads 12 allows control of the size of the cavities formed in the cups, and consequently the size of the particles meso-dots. The thickness of the film can be controlled based on deposition conditions of metals or so, such as sputtering time of metal particles for example. Source materials for the colloidal beads can properly be selected, where selecting a source material which is capable of forming a stable colloidal beads ensures stable producing of the meso-cups structure and the meso-dots structure. It is also to be noted that the method allows use of any of single metals, metallic alloys and even non-metallic materials for the film.

The following paragraphs will detail the individual process steps.

(1) Preparation of Colloidal Dispersion Liquid

The colloidal dispersion liquid of the colloidal beads is first prepared. There is no special limitation on the source materials for producing the colloidal beads, and any of those not reactive with a metal or metal compound to -be deposited thereon are available. Since the colloidal beads must finally be removed from inside of the meso-cup-structured film, it is necessary to use the source material therefor having the decomposition temperature or boiling point lower than the fusing temperature of the film material for the case where the removal is effected by heating. On the other hand, for the case where the removal is effected by dissolution into a solvent, it is necessary to use the source materials soluble to a solvent to be used. While both of inorganic and organic materials are allowable for use in the colloidal beads, organic colloidal beads are more preferable because of excellent uniformity of the composition and size, ease of removal from inside of the film, and less residues in the post processing.

It is also allowable to use surface-coated colloidal beads. Formation of the meso-cup-structured film using the surface-coated colloidal beads allows the coating on such beads to be transferred onto the inner wall of the meso-cups, which successfully forms a functional layer in the cavities. For example, formation of a meso-cup-structured nickel film using a colloidal dispersion liquid containing thin-gold-plated beads results in a meso-cups-structured film having the individual cups (cavities) plated with gold on the inner walls thereof. Agents for coating the colloidal beads can be selected from organic or inorganic materials having boiling points equivalent to or higher than the decomposition temperature of the colloidal beads and lower than the fusing temperature of the material composing the meso-cups.

The size of the colloidal beads can be selected depending on the cavity size of the meso-cups to be produced. As for the meso-dots, the size of the particles cannot unconditionally be determined only by the size of the colloidal beads since the fine particles are formed by shrinkage, so that it is important to select the size also considering the thickness of the film deposited by sputtering. In the present invention, the colloidal beads preferably has a size of 100 □m or below, and more preferably 1 □m or below (i.e. in the order of nanometer). In the present invention, the colloidal beads preferably have a uniform size. While the shape of the colloidal beads is not specifically limited, it is preferably spherical since the beads are uniformly arranged when the layer of the colloidal beads is formed by coating the dispersion liquid thereof. The colloidal beads used in the present invention are commercially available typically in a form obtained by the liquid phase process such as soap-free method. It is also allowable to use those obtained by the vapor phase process or solid phase process.

The colloidal dispersion liquid is preferably such that having the colloidal beads uniformly dispersed therein. Using surface-treated colloidal beads is advantageous in that improving the affinity of such colloidal beads with the solvent, which results in the dispersion liquid having an excellent dispersion stability. Available surface treatment agents can properly be selected depending on composition of the beads and solvent, where typical examples thereof include surfactants which are typified by anionic surfactants such as aerosol-OT and sodium dodecylbenzenesulfonate; nonionic surfactant such as alkyl ester of polyalkylglycol and alkylphenyl ether; and fluorine-containing surfactant.

While the solvent is not specifically limited so far as it can be removed by drying and vaporization (or further by calcination if included in the process), it is preferably selected in consideration of combination with the substrate, since too low affinity with the substrate will make it difficult to form the film due to a large surface tension when the liquid is coated on the substrate. Moreover, use of a solvent which is too volatile will make the liquid dry before casting, and again make it difficult to form a uniform film, so that it is preferable to select the solvent while also taking the film forming conditions into account. It is still preferable that the colloidal dispersion liquid has a certain degree of viscosity since it is coated on the substrate so as to be converted into the film. The solvent or dispersion liquid may have the certain degree of viscosity itself, or a viscosity improver may be added thereto in order to control the viscosity of the colloidal dispersion liquid. Preferable viscosity of the colloidal dispersion liquid generally resides in a range from 1 to 10 mPa·S while being variable depending on the coating method.

The concentration of the colloidal beads in the colloidal dispersion liquid is preferably low, which preferably resides within a range from 0.0001 to 1.0 wt %, and more preferably in a range from 0.001 to 0.1 wt %. Using a dilute liquid is preferable because the colloidal beads will never be stacked with each other when cast on the substrate, which ensures more stable formation of-the regular arrangement in the structure.

The colloidal dispersion liquid may be such that being obtained from the liquid phase reaction after being adjusted from the foregoing viewpoints, or may be such that uniformly dispersing the colloidal beads into a solvent. The liquid may also be used as a coating liquid after being subjected to more powerful dispersion process such as ultrasonic dispersion or dispersion using a homogenizer.

(2) Coating of Colloidal Dispersion Liquid (First Step)

Next, the prepared colloidal dispersion liquid is coated on the surface of the substrate so as to form a film (FIG. 1(a)), and the film is then dried so as to vaporize the solvent contained therein, thereby that the colloidal beads assemble themselves on the substrate (FIG. 1(b)). The substrate used herein preferably has a smooth surface without irregularity so as to facilitate regular organization of the colloidal beads. While the substrate preferably has a flat surface from the viewpoint of simple coating, a surface other than flat one is also allowable provided that the organization of the colloidal beads will not be destroyed after drying, and that the thickness of the film formed thereon by sputtering or the like will not become irregular to a large extent. There is no special limitation on the material for composing the substrate, but yet silicon wafer is preferably used for its excellent smoothness, workability, relatively low price, commercial availability, and no reactivity with the colloidal beads.

Also method of the coating is not specifically limited, where examples thereof include spin coating, dip coating, spraying and ultrasonic-assisted drying method.

The colloidal coated film formed by the coating is then preferably heated at relatively low temperatures so as to vaporize the solvent. In the drying process, gradual vaporization of the solvent allows the colloidal beads as a solute to organize themselves, which successfully leads to a uniform regular arrangement. Preferable range of the heating temperature in this process may differ depending on the viscosity or volatility of the solvent, where heating at 25 to 50° C. for 10 to 30 minutes is preferable for the liquid having a relatively low concentration and a viscosity of approx. 1 to, 10 mPa·S.

(3) Formation of Film (Second Step)

Next the film of a metal and/or metal compound is formed on the colloidal beads arranged on the substrate (FIG. 1(c)). On the colloidal beads a cup-structured film is formed. The film covers the colloidal beads in a form that the individual cups are placed facedown. In the formation of the film, it is necessary to deposit a metal or metal compound until at least the individual cup-formed portions covering the adjacent colloidal beads are bound with each other. If the film formation is insufficient, the film may break later and may even fail in form the structured material in the next step. Thus the thickness of the sputtered film is preferably 1 nm to 1 □m.

The film is preferably formed by depositing fine particles of a metal and/or metal compound, where the deposition may be effected either of vapor-phase process and liquid-phase process. Examples of the vapor-phase process include general vapor deposition, ion sputtering, vacuum deposition and CVD. Examples of the liquid-phase process include spray method using nano-particle sol, and spray thermal decomposition method. While any of the methods are allowable, particularly preferable is the ion sputtering method. The CVD process is available for the case where a compound film is formed. Methods other than the CVD process are also applicable to formation of the compound film such as oxide and nitride films, by controlling the atmosphere for the film formation.

Species of the metal or metal compound are not specifically limited so far as they are available in the vapor-phase process such as sputtering, or in the liquid-phase process such as spray method using nano-particle sol and spray thermal decomposition method, where metal, alloy or metal compound such as metal oxide is available. For the case where the metal structured material is prepared, it is preferable to use relatively noble and inert metal or alloy, which is typified by gold, platinum, palladium, silver, copper and nickel. For the case where the structured material comprised of a compound is prepared in the later step, the source material of the compound may properly be selected. According to the ion sputtering method, it is also allowable to arbitrarily control the compositional ratio of two or more source materials by sputtering such source materials in a predetermined ratio, where varying such predetermined ratio during the sputtering process further makes it possible to obtain a -structured material showing a gradient compositional ratio.

(4) Removal of Colloidal Beads (Third Step)

After the cup-structured film is formed, the colloidal beads are removed to empty the cup to thereby form the cavities (FIG. 1(d)). The colloidal beads can be removed by decomposition, vaporization and/or sublimation thereof under heating at a temperature lower than the fusing temperature of the film. Proper control of the heating conditions successfully results in removal of the colloidal beads without causing any residue.. For an exemplary case that the colloidal beads comprised of an organic material cause carbon or other residues after decomposed within a short time, it is therefore preferable to adjust the heating conditions so that the decomposition proceeds in a more moderate manner. The film starts to fuse at a temperature lower than that shown in a bulk state.

It is to be noted now that fusing temperature described herein is not the melting point shown by the bulk material, but is a temperature whereat the film fuses. It has reported in various literatures that metal particle fuses at a temperature lower than the melting point of the bulk metal (e.g., Castro T. et al, Phys. Rev. B 1990, 42, 8548).

Besides heating, the colloidal beads can be removed also by dissolution into a solvent. The solvent may be alkaline or acidic solution. It is still also allowable to combine both methods to remove the colloidal beads.

The heating proceeds removal of the colloidal beads and accelerates self-organization of the cup-structured film, which promotes mutual connection of the cups so as to produce the structure having cavities (referred to as meso-cups) having a uniform internal cavity size. The structure has a structure in which the hollow, cup-formed structural units are arranged in continuous and two-dimensional manners while directing the openings of the cups towards the substrate (facedown). Heating at a higher temperature which will not decompose the cup structure can allow the film to crystallize so as to produce crystalline meso-cups. The crystallinity of the meso-cups can be confirmed by X-ray diffractometry. In an exemplary case where the film is composed of a metal, the crystallinity is expressed in an X-ray diffraction pattern, which crystallinity is similar to that shown by the bulk metal (the similarity can be judged if the peaks appear almost at the same positions, where smaller peak intensity is of no significance).

When the heating temperature is raised to the fusing temperature of the film or higher, the meso-cup-structured film fuses, where the film shrinks towards the substrate so as to reduce the surface tension (FIG. 1(d′)), which produces fine particles comprised of a metal or metal compound regularly arranged in a two-dimensional dot pattern on the substrate (FIG. 1(e)). While the individual particles in FIG. 1(e) are expressed as spheres, shape of the particles may vary depending on the heating conditions or so, and may sometimes have a scaly shape with a facet.

The meso-cups produced in the present invention, which are characterized by its regularly-arranged cavities, are applicable to porous electrode, reflecting plate and low-k (low-dielectric-constant) material and so forth. The meso-dots, which are characterized by the regularly arrangement of nano-particles, are applicable to reflecting plate, electrode (e.g., battery electrode, electrode capable of raising efficiency of light-emitting diode or the like), capacitor having an ultra-high capacity and wave-length-selective reflecting plate.

### EXAMPLES

The present invention will further be detailed referring to specific Examples. It is to be noted that any materials, reagents, ratios of use thereof and operations shown in the Examples below can properly be modified without departing from the spirit of the present invention. Thus the present invention is by no means limited to the Examples described below.

### Example 1

A silicon wafer was cleaned by ultrasonic cleaning for 10 minutes in a bath containing a 1:1 (v/v) solution of ethanol (Kanto Kagaku, 99.5%) and distilled water. A colloidal dispersion-liquid containing polystyrene latex (PSL) having an average size of 79 nm was separately prepared. PSL was a product of JSR (Japan Synthetic Rubber).

The colloidal dispersion liquid was then dropped on the surface of the silicon wafer, dried at 40° C. until the solvent in the droplets completely vaporizes, and successively dried at 100° C. for 10 minutes to thereby allow the PSL beads to come fully close to with each other. Palladium nano-particles were then deposited on the beads by sputtering using an ion sputtering apparatus (product of Hitachi, Ltd., Model E-1010) under a vacuum condition of 0.05 Torr for 5 minutes. The obtained samples was then calcined according to a heating cycle shown in FIG. 2 at 450° C. for 1 hour, to thereby decompose and remove the PSL beads. A sample having a meso-cups structure was thus obtained.

Another sample was produced similarly to as described in the above except that PSL beads having an average size of 254 nm were used in place of those having an average size of 79 nm.

Thus obtained samples were observed under a SEM (product of Hitachi, Ltd., Model S-500, operated at 20 kV).

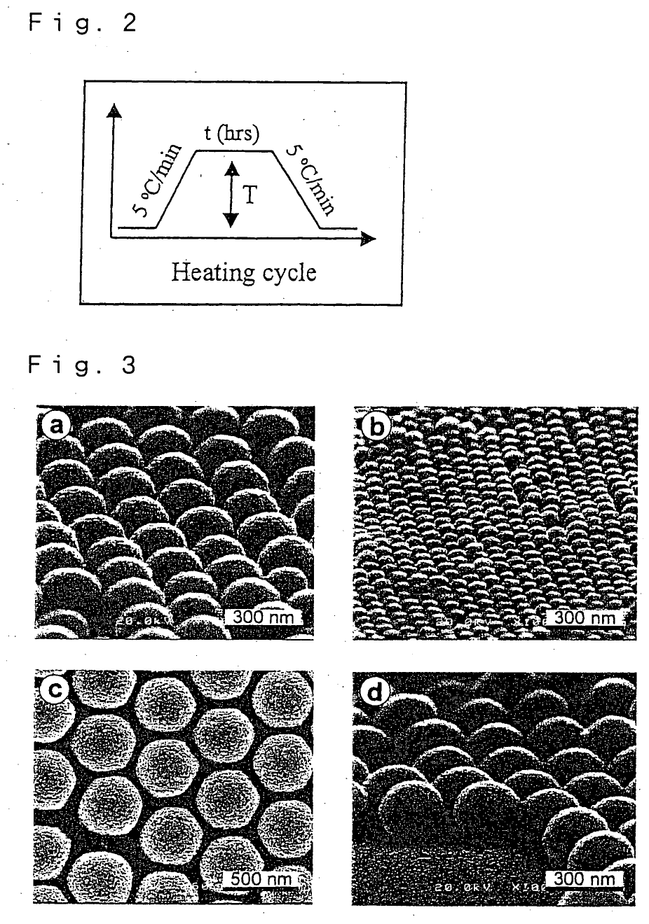

FIG. 3(a) shows a tilt view of the sample produced using the PSL beads having an average size of 254 nm, and FIG. 3(b) shows that of the sample produced the PSL beads having an average size of 79 nm. FIG. 3(c) is a top view of the sample produced using the PSL beads having an average size of 254 nm, and FIG. 3(d) shows a tilt view of the edge of the sample using the PSL beads having an average size of 254 nm.

While a certain degree of tetragonal packing was observed, metal cups were found to be arranged mainly in the form-of hexagonal packing. Degan et al. previously reported in Nature (1997, Vol. 389, p.827) that droplets of a colloid placed on a flat surface tends to form a ring-like structure by drying. The same patterns were observed in FIGS. 3(a) and 3(b); a three-dimensional hexagonal packing of the PSL beads around the center of the ring path, and two-dimensional hexagonal packing away form the ring path. It was also found from FIG. 3(c) that there was a metallic networks connecting the nearest neighbor bead surfaces. The size of the metallic connector produced by the ion sputtering was found to be less than 20 nm. It was further made clear from the SEM image shown in FIG. 3(d) that each cup has an opening on the bottom thereof.

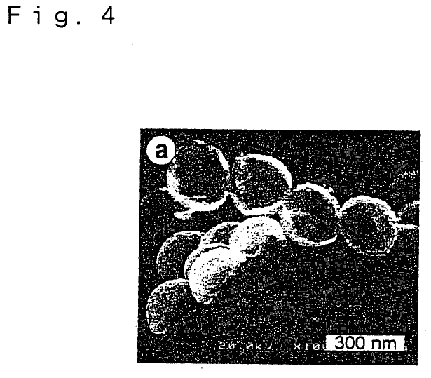

A portion of the cup-structured calcined film produced using the 254-nm PSL beads was removed and observed under the SEM. FIG. 4 shows an image obtained by the SEM observation. It was found that each cup had an eggshell-like form, which revealed that the calcined material had fine cavities. The edge formed by removal of the film was found to have cylindrical spaces.

### Example 2

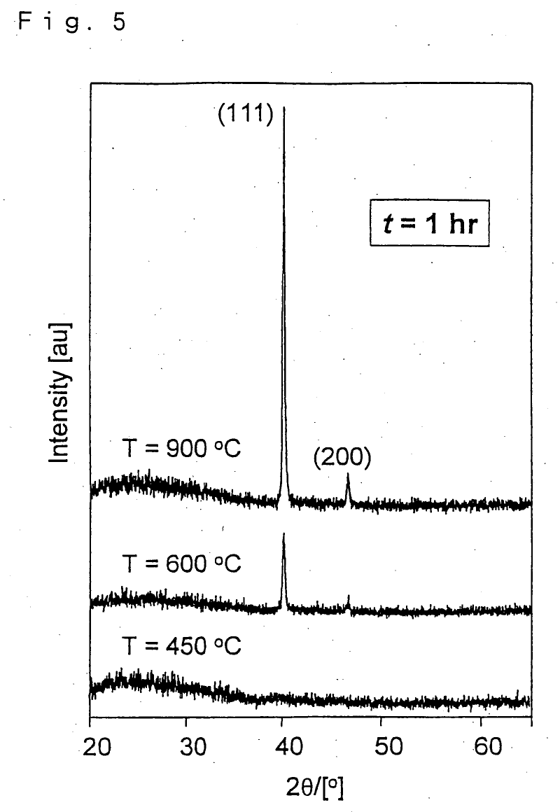

Calcined materials were manufactured using the 254-nm PSL beads similarly to Example 1, except that the calcination temperatures were respectively altered to 600° C. and 900° C. It is now defined that a calcined material obtained at a calcination temperature of 450° C. is referred to as Sample 1, that obtained at 600° C. as Sample 2, and that obtained at 900° C. as Sample 3. These samples 1 through 3 were subjected to X-ray diffractmetry (using diffractometer Model RINT2000, product of Rigaku Corporation, measured at room temperature). FIG. 5 shows the individual diffraction patterns.

While Sample 1 showed no peaks suggesting crystallinity inherent to the bulk metal, Sample 2 clearly showed such peaks at (111) and (200) positions, which peaks were similar to those shown by bulk palladium, and Sample 3 showed more intense peaks. This indicates that Samples 2 and 3 have a crystallinity equivalent to that of bulk palladium.

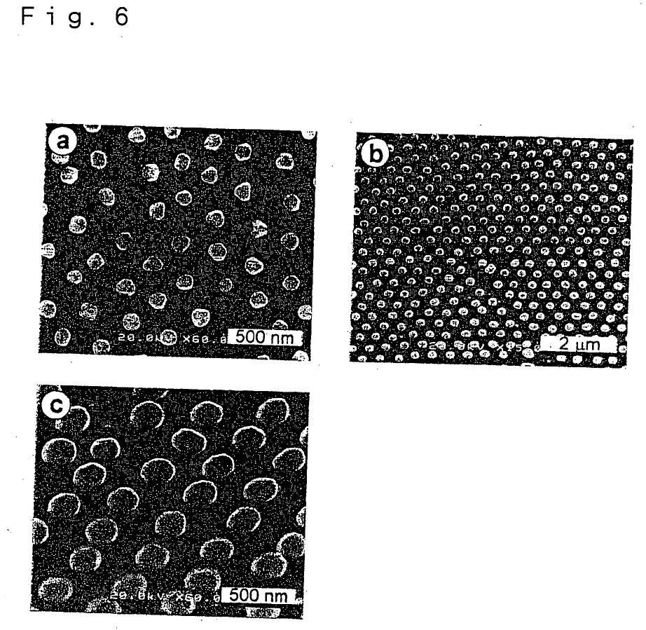

FIG. 6(a) shows a top view of Sample 3. It was found from FIG. 6(a) that Sample 3 had metal particles arranged in a dot pattern, where the individual metal particles were formed by the fused palladium film and individually located at the center of the individual cups. Each particles was found to have a diameter of approx. 100 nm, and the distance between spot centers was precisely similar to that of the cup centers. While the melting point of bulk palladium is 1,454° C., the cup-structured palladium film was supposed to fuse at a far lower temperature of 900° C., and formed the particles.

### Example 3

A calcined sample was manufactured similarly to the method for Sample 3, except that a 453-nm PSL (product of Duke Scientific Corporation) was used (Sample 4).

A top view of Sample 4 was shown in FIG. 6(b), and a tilt view thereof in FIG. 6(c).

It was found that the diameter of the particles was approx. 200 nm. It was also found that the individual particles had a facet face.

As has been described in the above, the present invention can provide methods for readily and rapidly producing a structure having cavities regularly arranged, and a structure having fine particles regularly arranged in a dot pattern by adjusting setting of the conditions. The present invention can also provide a novel structure having regularly arranged cavities (referred to as “meso-cup”), and a novel structure having a regularly arranged fine particles (referred to as “meso-dot”).

Having described our invention as related to the present embodiments, it is our intention that the invention not be limited by any of the details of the description, unless otherwise specified, but rather be construed broadly within its spirit and scope as set out in the accompanying claims.

1. A method for producing a structure having cavities comprising:
a first step of coating a colloidal dispersion liquid on a substrate and then drying to thereby form a layer of colloidal beads on said substrate;
a second step of forming a film comprising a metal and/or metal compound on the surfaces of said colloidal beads placed on said substrate; and
a third step of removing said colloidal beads thereby to form cavities in place of said colloidal beads.

2. The method of claim 1, wherein said colloidal beads are made of an organic material.

3. The method of claim 1, wherein said film in said second step is formed by depositing a metal and/or metal compound on the surface of said colloidal beads by the vapor phase process.

4. The method of claim 1, wherein said film in said second step is formed by depositing a metal and/or metal compound on the surfaces of said colloidal beads by the liquid phase process.

5. The method of claim 1, wherein said colloidal beads in said third step are removed by decomposition, vaporization and/or sublimation under heating.

6. The method of claim 1, wherein said colloidal beads in said third step are removed by decomposition, vaporization and/or sublimation while being heated to a temperature lower than the fusing temperature of said film.

7. The method of claim 1, wherein said colloidal beads in said third step are removed by dissolving said colloidal beads into a solvent.
